(19) United States
(12) Patent Application Publication
(10) Pub. No.: US 2021/0285995 A1
(43) Pub. Date: Sep. 16, 2021

(54) TIME SYNCHRONIZATION USING POWER SYSTEM SYNCHROPHASOR MEASUREMENTS

(71) Applicants: University of Tennessee Research Foundation, Knoxville, TN (US); Traffic Technology Services, Inc., Beaverton, OR (US)

(72) Inventors: Yilu Liu, Knoxville, TN (US); Ling Wu, Andover, MA (US); Jingtao Ma, Portland, OR (US); Thomas Bauer, Beaverton, OR (US)

(21) Appl. No.: 16/818,401

(22) Filed: Mar. 13, 2020

(51) Int. Cl. G01R 29/18; G01R 19/25; G01R 19/175

(52) U.S. Cl. CPC G01R 29/18; H04Q 2209/60; G01R 19/175; G01R 19/2513

(57) ABSTRACT

A method includes performing by a processor: receiving a plurality of power system synchrophasor measurements over a time interval from a plurality of phasor measurement units (PMUs) in a power system, determining a variation in frequency of a power signal generated by the power system based on the plurality of power system synchrophasor measurements, and determining a clock time shift based on the variation in frequency of the power signal.

### BACKGROUND

The present disclosure relates to power systems, and, in particular, to the effects of frequency variation in power systems.

Automotive driver assist features in cars are becoming commonplace. Automotive manufacturers are using automation to assist with vehicle safety and routing. Many organizations—both governmental and commercial—are working on new technologies that may enable greater safety and efficiency in automotive transportation. As driving becomes more automated, some research predict that at least 80% of all accidents can be avoided, carbon emissions reduced substantially, and more effective use of road and parking space can be achieved.

Vehicle-to-vehicle communication technology is currently provided on some cars and may be widespread in the future. Vehicle-to-infrastructure communication technology is being developed and tested and is also expected to become widespread in the future.

The IEEE 802.11p industry standard has been developed to support vehicle-to-infrastructure communication and many governmental authorities and regulatory bodies around the world have allocated frequencies near 5 GHz for vehicular communications. With the cars available now that can talk to each other, vehicle-to-infrastructure is expected to be deployed in more areas to improve vehicular safety and driver convenience.

FIG. 1A illustrates a conventional vehicle-to-infrastructure system in which a roadside unit is used to provide connectivity support to passing vehicles. As shown in FIG. 1A, a roadside unit (RSU) 110 is used to communicate with vehicles near an intersection, such as vehicle 120, to provide each other with information, such as safety warnings and traffic information. The RSU 110 and the communication unit in the vehicle 120 are both dedicated short-range communications (DSRC) devices. DSRC works in the 5.9 GHz band with a bandwidth of 75 MHz and an approximate range of 1000 meters. The communication between nodes comprising vehicles and roadside units may be part of an overall intelligent transportation system (ITS).

Operation of vehicle-to-infrastructure communication may be illustrated by way of example with reference to FIG. 1A. In the scenario illustrated in FIG. 1A, a traffic signal controller 130 transfers information to the RSU 110 regarding the signal phase of the traffic light 140 and the amount of time remaining until the light changes. The RSU 110 transmits the traffic light 140 information to the vehicle 120. The on-board communication unit in the vehicle 120 receives the RSU 110 information and displays an appropriate alert regarding the state of the traffic signal 140 for the driver. For example, the vehicle may provide a visual and/or auditory alert that the driver is at risk of running a red light. A backhaul connection 150, such as a fiber optic and/or electrical cable may be used to connect a traffic management center 160 to the traffic signal controller 130 and/or the RSU 110. The traffic management center 160 may manage the flow of traffic on surrounding roads and highways based on data collected from vehicles and RSUs, such as the vehicle 120 and the RSU 110.

Vehicle-to-infrastructure communication systems, however, rely on accurate timing between traffic control units and their management systems, such as the traffic signal controller 130 and the traffic management center 160. Clocks in the traffic management center 160 and the various traffic signal controllers 130 under the traffic management center's 160 control may be synchronized. The accuracy of the clocks, however, may be impacted by the frequency of the power signals used to operate them.

Typically, traffic signals are powered by the local electricity lines, which provide energy to light up the signals along with its control and communication systems. There may be numerous types of clocks in millions of traffic signals. The most common types of clocks that are based on electricity will be described hereafter. There are generally 3 types of counting schemas applied in electric clocks. The first is a synchronous clock that may operate in response to a frequency divider circuit, which is shown in FIG. 1B. The frequency divider circuit includes a rectifier 170, divider 172, divider 174, divider 176, quartz drive circuit 178, changeover relay 180, and clock 182, which are configured as shown. The rectifier 170 in conjunction with the dividers 172, 174, and 176 reduce the AC power frequency from 60/50 Hz to 0.5 Hz. The changeover relay 180 may select between the output of the divider chain 172, 174, 176 and the quartz drive circuit 178. Every time the AC current/voltage wave crosses zero, one second is added. For clocks connecting with the US power grid, the actual time for adding one second is f/60, where f is the frequency.

A second counting scheme is based on cycle counting. In this scheme, a count is made every time the AC current crosses zero. When the signal crosses zero twice it is counted as one cycle. Every continuous 60/50 cycles is recognized as one second forward and one second is added to the clock. For clocks connecting with the US power grid, the actual time for adding one second is f/60, where f is the frequency.

A third counting scheme is based on a small rotating motor. For example, a small synchronous rotating motor may be driven by AC power where the rotation of the shaft is synchronized with the frequency of the supply current. The rotation period is exactly equal to an integral number of AC cycles. The stator of the electric motor creates a magnetic field, which rotates in time with the oscillations of the line current. The rotor with a permanent magnet or electromagnet turns in step with the stator field at the same rate, and, as a result, provides the second synchronized rotating magnetic field of an AC motor. The rotating speed of the synchronous motor may be synchronized with the power grid frequency and may be given as the following equation:

$$N = 120 * \frac{f}{p}$$

Where f is the power frequency, N represents the rotation speed in rpm, and p stands for the number of pole per phase. The rotation speed designed by the manufacturer is displayed on the surface of the motor. When applied in electric clocks, it counts the rotation and adds one second when the rotation cycles reach the amount as designed. Eventually, the motor recognizes f/60 as one second.

Although there are multiple mechanical schemas of electric clocks, the basic principle associated with electricity frequency is that it may be associated with a 1 second interval in a clock. If the frequency is ideally stable at 60 Hz, then the clock may keep accurate time. If the frequency is higher than 60 Hz, then there would be more cycles in one second. However, the schema of clock may not recognize the change. The clock time would be faster than the correct clock time. Conversely, if the frequency is lower than 60 Hz, then there would be less than 60 cycles in one second. The clock would wait until the cycles reach 60 to add one second so the clock time would be slower than the correct clock time.

The frequency of a power system may be affected by the balance between power generation and load consumption. Power consumption and/or power generation may both vary, which may result in the two rarely being precisely in balance. Thus, it is not uncommon for the frequency of a power system signal to vary slightly over time from the desired frequency of 60 Hz. Because of the frequency fluctuation around the nominal frequency value, a clock may not run at exactly the same rate as a reference clock. After a period of time, clocks may drift apart or gradually desynchronize from each other. The drift caused by frequency fluctuation may be invisible to operators or consumers.

### SUMMARY

In some embodiments of the inventive concept, a method comprises performing by a processor: receiving a plurality of power system synchrophasor measurements over a time interval from a plurality of phasor measurement units (PMUs) in a power system, determining a variation in frequency of a power signal generated by the power system based on the plurality of power system synchrophasor measurements, and determining a clock time shift based on the variation in frequency of the power signal.

In other embodiments, determining the variation in frequency of the power signal comprises: determining a first variation in frequency of the power signal based on at least a first portion of the plurality of power system synchrophasor measurements and determining a second variation in frequency of the power signal based on at least a second portion of the plurality of power system synchrophasor measurements. Determining the clock time shift comprises: determining a first clock time shift based on the first variation in frequency of the power signal and determining a second clock time shift based on the second variation in frequency of the power signal.

In still other embodiments, the method further comprises determining a first clock time adjustment and a second clock time adjustment based on the first clock time shift and the second clock time shift, respectively, to reduce a time offset between the first clock and the second clock.

In still other embodiments, a vehicular traffic management center operates based on the first clock and a traffic signal controller operates based on the second clock, the traffic signal controller being under control of the vehicular traffic management center.

In still other embodiments, the method further comprises communicating the first clock time adjustment to the vehicular traffic management center and communicating the second clock time adjustment to the traffic signal controller.

In still other embodiments, communicating the first clock time adjustment comprises communicating the first clock time adjustment to the vehicular traffic management center via a packet switched connection and communicating the second clock time adjustment comprises communicating the second clock time adjustment to the traffic signal controller via the packet switched connection.

In still other embodiments, the packet switched connection comprises an Ethernet connection.

In still other embodiments, the first clock time adjustment comprises first Multiprotocol Label Switching (MPLS) packet data and the second clock time adjustment comprises second MPLS packet data.

In still other embodiments, a first label of the first MPLS packet data comprises a first identifier that identifies a first communication service provider. A second label of the second MPLS packet data comprises a second identifier that identifies a second communication service provider.

In still other embodiments, the method further comprises determining a clock time adjustment based on the clock time shift and communicating the clock time adjustment to an entity that operates based on the clock.

In still other embodiments, the method further comprises generating an alert based on the clock time shift.

In still other embodiments, the method further comprises communicating the alert to an entity that operates based on the clock.

In some embodiments of the inventive concept, a system comprises a processor and a memory coupled to the processor and comprising computer readable program code embodied in the memory that is executable by the processor to perform operations comprising: receiving a plurality of power system synchrophasor measurements over a time interval from a plurality of phasor measurement units (PMUs) in a power system, determining a variation in frequency of a power signal generated by the power system based on the plurality of power system synchrophasor measurements, and determining a clock time shift based on the variation in frequency of the power signal.

In further embodiments, determining the variation in frequency of the power signal comprises: determining a first variation in frequency of the power signal based on at least a first portion of the plurality of power system synchrophasor measurements and determining a second variation in frequency of the power signal based on at least a second portion of the plurality of power system synchrophasor measurements. Determining the clock time shift comprises: determining a first clock time shift based on the first variation in frequency of the power signal and determining a second clock time shift based on the second variation in frequency of the power signal.

In further embodiments, the operations further comprise determining a first clock time adjustment and a second clock time adjustment based on the first clock time shift and the second clock time shift, respectively, to reduce a time offset between the first clock and the second clock.

In further embodiments, a vehicular traffic management center operates based on the first clock and a traffic signal controller operates based on the second clock, the traffic signal controller being under control of the vehicular traffic management center.

In further embodiments, the operations further comprise communicating the first clock time adjustment to the vehicular traffic management center and communicating the second clock time adjustment to the traffic signal controller.

In some embodiments of the inventive concept, a computer program product comprises a tangible computer readable storage medium comprising computer readable program code embodied in the medium that is executable by a processor to perform operations comprising: determining a first variation in frequency of the power signal based on at least a first portion of the plurality of power system synchrophasor measurements and determining a second variation in frequency of the power signal based on at least a second portion of the plurality of power system synchrophasor measurements. Determining the clock time shift comprises: determining a first clock time shift based on the first variation in frequency of the power signal and determining a second clock time shift based on the second variation in frequency of the power signal.

In other embodiments, the operations further comprise determining a first clock time adjustment and a second clock time adjustment based on the first clock time shift and the second clock time shift, respectively, to reduce a time offset between the first clock and the second clock.

In other embodiments, a vehicular traffic management center operates based on the first clock and a traffic signal controller operates based on the second clock, the traffic signal controller being under control of the vehicular traffic management center. The operations further comprise: communicating the first clock time adjustment to the vehicular traffic management center and communicating the second clock time adjustment to the traffic signal controller.

Other methods, systems, articles of manufacture, and/or computer program products, according to embodiments of the inventive concept, will be or become apparent to one with skill in the art upon review of the following drawings and detailed description. It is intended that all such additional systems, methods, articles of manufacture, and/or computer program products be included within this description, be within the scope of the present inventive concept, and be protected by the accompanying claims.

### BRIEF DESCRIPTION OF THE DRAWINGS

Other features of embodiments will be more readily understood from the following detailed description of specific embodiments thereof when read in conjunction with the accompanying drawings, in which:

FIG. 1A is a block diagram that illustrates a conventional vehicle-to-infrastructure system in which a roadside unit is used to provide connectivity support to passing vehicles;

FIG. 1B is a block diagram of a synchronous clock that incorporates frequency dividers;

FIG. 2 is a block diagram that illustrates a power distribution network including a time synchronization capability in accordance with some embodiments of the inventive concept;

FIG. 3 illustrates a data processing system that may be used to implement a Distribution Management System (DMS) processor associated with a power system of FIG. 1 in accordance with some embodiments of the inventive concept;

FIG. 4 is a block diagram that illustrates a software/hardware architecture for use in a DMS processor for time synchronization based on synchrophasor measurements in a power system in accordance with some embodiments of the inventive concept;

FIG. 5 is a block diagram that illustrates a multiprotocol label switching (MPLS) label and internet protocol (IP) packet in accordance with some embodiments of the inventive concept;

FIGS. 6-7 are flowcharts that illustrate time synchronization operations using synchrophasor measurements in a power system in accordance with some embodiments of the inventive concept;

FIG. 8 is a chart that illustrates predicted and measured time shift or drift based on power system frequency variations in accordance with some embodiments of the inventive concept;

FIG. 9 is a Graphical User Interface (GUI) of a system for estimating time shift or drift of an electric clock in accordance with some embodiments of the inventive concept;

FIG. 10 is a display interface showing an time drift estimation according to some embodiments of the inventive concept;

FIG. 11 is a display interface showing a query log of a signal controller according to some embodiments of the inventive concept;

FIG. 12 is a text file of a query log of a signal controller according to some embodiments of the inventive concept;

FIGS. 13 and 14 are display interfaces showing a comparison of estimated time drift results with measured time drift results according to some embodiments of the inventive concept;

FIG. 15 is a text file of a time drift comparison between estimated time drift results and measured time drift results according to some embodiments of the inventive concept;

FIG. 16 is a chart that illustrates predicted and measured time shift or drift based on frequency data from different states according to some embodiments of the inventive concept;

FIG. 17 is a chart that illustrates predicted and measured time shift or drift based on frequency data from a single state according to some embodiments of the inventive concept;

FIG. 18 is a chart that illustrates predicted and measured time shift or drift based on average frequency data according to some embodiments of the inventive concept;

FIG. 19 is a GUI of a system for estimating time shift or drift of an electric clock over a long-term time interval in accordance with some embodiments of the inventive concept.

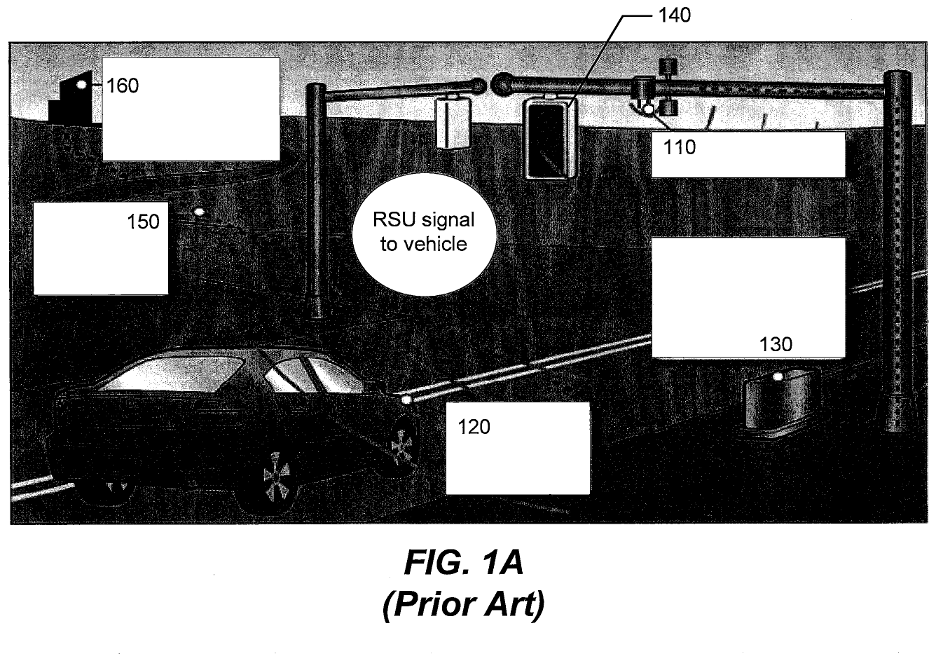

### DETAILED DESCRIPTION

In the following detailed description, numerous specific details are set forth to provide a thorough understanding of embodiments of the present disclosure. However, it will be understood by those skilled in the art that the present invention may be practiced without these specific details. In some instances, well-known methods, procedures, components and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

As used herein, the term “data processing facility” includes, but it is not limited to, a hardware element, firmware component, and/or software component. A data processing system may be configured with one or more data processing facilities.

As used herein, the term “real-time” may mean an operation is performed without inserting any artificial scheduling or processing delays.

Both traditional traffic flow management systems as well as management of advanced self-driving vehicles rely on efficient and reliable operation of traffic control units, such as traffic lights. A traffic signal controller may be in real-time communication with a tragic management center to inform the traffic management center of the state of a traffic light and may receive commands therefrom to control the periods between the various light states. As a result, clocks in the traffic signal controllers may be synchronized with the clock(s) used in the traffic management center. Many of the clocks used in the traffic signal controllers and traffic management centers are powered by electrical signals provided through the power grid. While these electrical power signals are designed to be at 60 Hz, the frequency may vary slightly, e.g., between 59.98 Hz and 60.02 Hz over time due to changes in load and other events. Note that the 60 Hz standard is used in some parts of the world. Other parts of the world use a different standard, such as 50 Hz, for example. The embodiments of the inventive concept described herein apply equally regardless of the particular frequency standard used. This may result in the clocks that operate using these power signals to experience a time shift by running too fast or slow based on the particular frequency variation. As a result, different clocks, such as clocks in the traffic control units and clock(s) in a traffic management center may lose synchronization with each other, which may affect the traffic management center's ability to efficiently control traffic using the traffic lights by way of the traffic controllers.

Some embodiments of the inventive concept stem from a realization power system synchrophasor measurements may be used to determine variations in frequency of a power signal. These synchrophasor measurements may be obtained through phasor measurement units (PMUs) placed throughout the power system delivery network including the power grid and/or terminal locations, such as 120 V wall outlets (or other voltage used based on the standard used at a particular geographic location) at customer sites. Based on the variation in frequency determined from these synchrophasor measurements, a clock time shift can be determined, which can then be used to perform time adjustment(s) in one or more clock(s). For example, these time adjustments may be applied to the clocks used in traffic controllers and a traffic management center to improve the time synchronization between the traffic controllers and the traffic management center. The improved synchronization may allow the traffic management center to more efficiently manage traffic through control of various traffic control units, such as traffic lights.

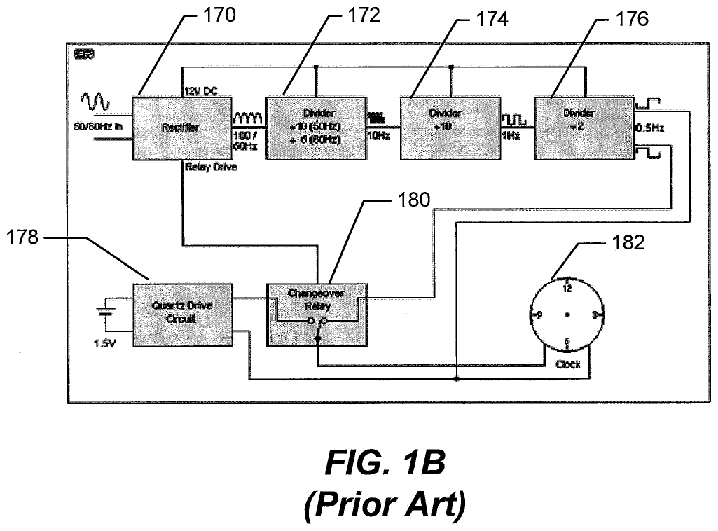

Referring to FIG. 2, a power system distribution network 200 including a time synchronization capability, in accordance with some embodiments of the inventive concept, comprises a main power grid 202, which is typically operated by a public or private utility, and which provides power to various power consumers 204a, 204b, 204c, 204d, 204e, and 204f. The electrical power generators 206a, 206b, and 206c are typically located near a fuel source, at a dam site, and/or at a site often remote from heavily populated areas. The power generators 206a, 206b, and 206c may be nuclear reactors, coal burning plants, hydroelectric plants, and/or other suitable facility for generating bulk electrical power. The power output from the power generators 206, 206b, and 206c is carried via a transmission grid or transmission network over potentially long distances at relatively high voltage levels. A distribution grid 210 may comprise multiple substations 216a, 216b, 216c, which receive the power from the transmission grid 208 and step the power down to a lower voltage level for further distribution. A feeder network 212 distributes the power from the distribution grid 210 substations 216a, 216b, 216c to the power consumers 204a, 204b, 204c, 204d, 204e, 204f, 230, and 260. The power substations 216a, 216b, 216c in the distribution grid 210 may step down the voltage level when providing the power to the power consumers 204a, 204b, 204c, 204d, 204e, 204f, 230, and 260 through the feeder network 212.

As shown in FIG. 2, the power consumers 204a, 204b, 204c, 204d, 204e, 204f, 230, and 260 may include a variety of types of facilities including, but not limited to, a warehouse 204a, a multi-building office complex 204b, a factory 204c, and residential homes 204d, 204e, and 204f. In addition, a vehicular traffic management center 260 may be a power consumer as well as a traffic signal controller 230 for one or more traffic lights 240. A feeder circuit may connect a single facility to the main power grid 202 as in the case of the factory 204c or multiple facilities to the main power grid 202 as in the case of the warehouse 204a and office complex 204b and also residential homes 204d, 204e, and 204f. Although only eight power consumers are shown in FIG. 2, it will be understood that a feeder network 212 may service hundreds or thousands of power consumers.

The power distribution network 200 further comprises a Distribution Management System (DMS) 214, which may monitor and control the generation and distribution of power via the main power grid 202. The DMS 214 may comprise a collection of processors and/or servers operating in various portions of the main power grid 202 to enable operating personnel to monitor and control the main power grid 202. The DMS 214 may further include other monitoring and/or management systems for use in supervising the main power grid 202. One such system is known as the Supervisory Control and Data Acquisition (SCADA) system, which is a control system architecture that uses computers, networked data communications, and graphical user interfaces for high-level process supervisory management of the main power grid.

According to some embodiments of the inventive concept, PMUs 218a, 218b, and 218c may be located at the substations 216a, 216b, and 216c, respectively. PMUs measure current and voltage by amplitude and phase at selected stations of the distribution grid 210. These measurements are known as synchrophasor measurements. Using Global Positioning System (GPS) information, for example, high-precision time synchronization may allow comparing measured values (synchrophasors) from different substations and/or terminal locations, e.g., consumer locations, distant to each other and drawing conclusions regarding the system state and dynamic events, such as power swing conditions. The PMUs 218a, 218b, 218c may determine current and voltage phasors, frequency, and rate of change of frequency and provide these measurements with time stamps for transmittal to the DMS 214 for analysis. The PMUs 218a, 218b, 218c may communicate with the DMS 214 over the network 220. The network 220 may be a global network, such as the Internet or other publicly accessible network. Various elements of the network 220 may be interconnected by a wide area network, a local area network, an Intranet, and/or other private network, which may not be accessible by the general public. Thus, the communication network 220 may represent a combination of public and private networks or a virtual private network (VPN). The network 220 may be a wireless network, a wireline network, or may be a combination of both wireless and wireline networks. Although the PMUs 218a, 218b, and 218c are shown as being located in the substations 216a, 216b, and 216c, it will be understood that the PMUs may be located in other locations within the distribution grid 210, within the main power grid 102, or even at consumer locations 204a, 204b, 204c, 204d, 204e, 204f, 230, and 260 such as, for example, in proximity to wall outlets or other power access points.

Although FIG. 2 illustrates an exemplary a power distribution network 200 including a time synchronization capability, it will be understood that embodiments of the inventive concept are not limited to such configurations, but are intended to encompass any configuration capable of carrying out the operations described herein.

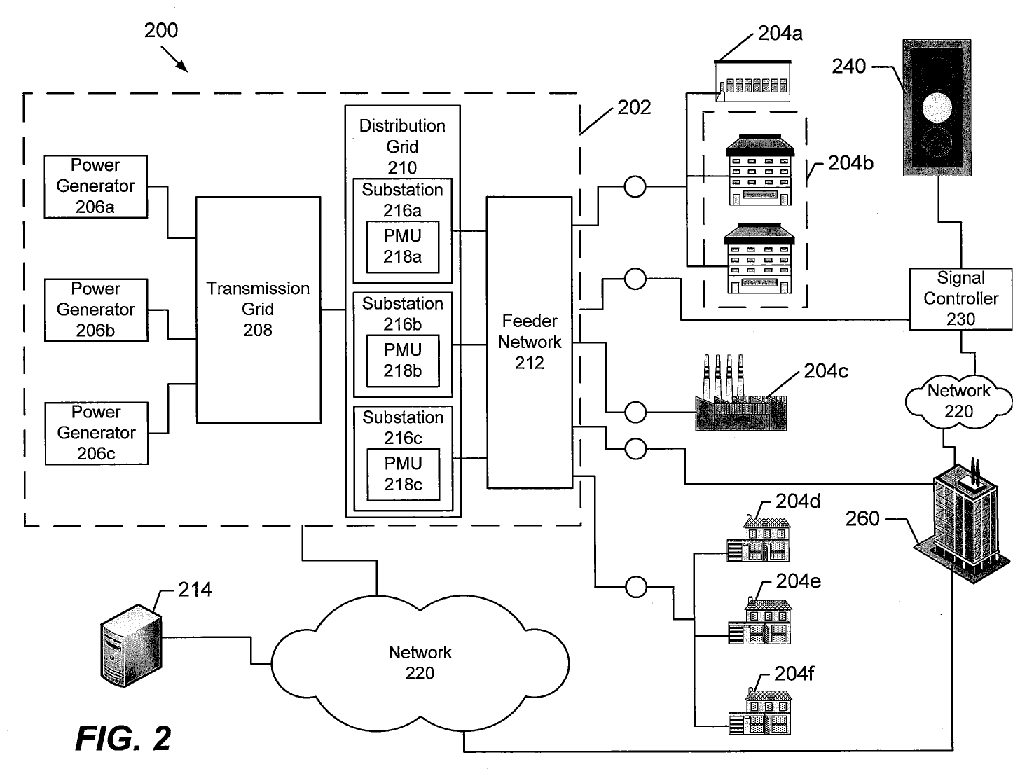

Referring now to FIG. 3, a data processing system 300 that may be used to implement the DMS 214 processor of FIG. 2, in accordance with some embodiments of the inventive concept, comprises input device(s) 302, such as a keyboard or keypad, a display 304, and a memory 306 that communicate with a processor 308. The data processing system 300 may further include a storage system 310, a speaker 312, and an input/output (I/O) data port(s) 314 that also communicate with the processor 308. The storage system 310 may include removable and/or fixed media, such as floppy disks, ZIP drives, hard disks, or the like, as well as virtual storage, such as a RAMDISK. The I/O data port(s) 314 may be used to transfer information between the data processing system 300 and another computer system or a network (e.g., the Internet). These components may be conventional components, such as those used in many conventional computing devices, and their functionality, with respect to conventional operations, is generally known to those skilled in the art. The memory 306 may be configured with a time synchronization module 316 that may provide functionality that may include, but is not limited to, determining variations in frequency of a power signal based on synchrophasor measurements obtained from PMUs 218a, 218b, and 218c in a power system including, for example, at or near wall outlets at customer locations and determining time shifts in one or more clocks based on the frequency variation in accordance with some embodiments of the inventive concept.

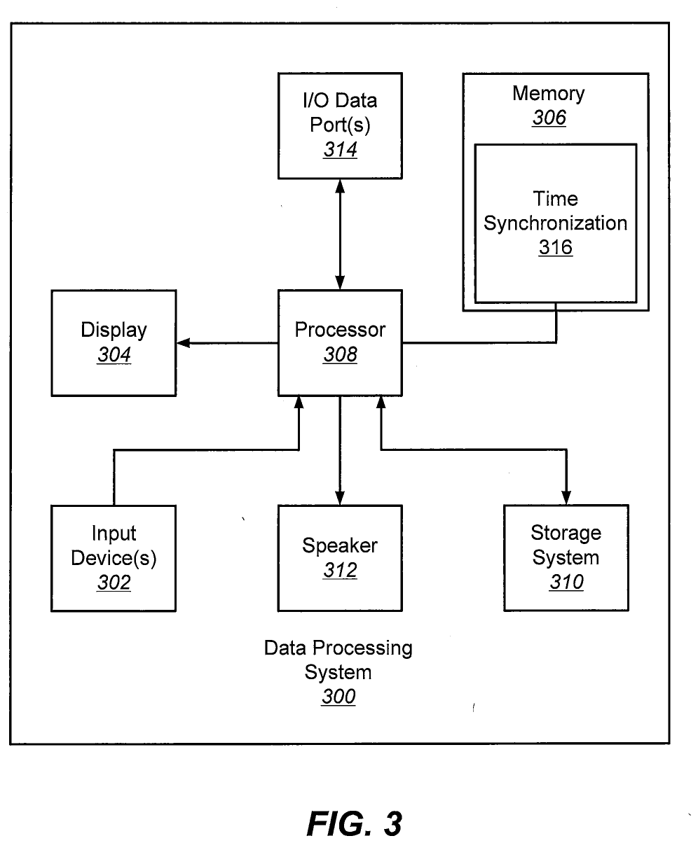

FIG. 4 illustrates a processor 400 and memory 405 that may be used in embodiments of data processing systems, such as the DMS 214 processor of FIG. 2 and the data processing system 300 of FIG. 3, respectively, for clock time shift adjustment and clock synchronization based on synchrophasor measurements, in accordance with some embodiments of the inventive concept. The processor 400 communicates with the memory 405 via an address/data bus 410. The processor 400 may be, for example, a commercially available or custom microprocessor. The memory 405 is representative of the one or more memory devices containing the software and data used for clock time shift adjustment and clock synchronization based on synchrophasor measurements in accordance with some embodiments of the inventive concept. The memory 405 may include, but is not limited to, the following types of devices: cache, ROM, PROM, EPROM, EEPROM, flash, SRAM, and DRAM.

As shown in FIG. 4, the memory 405 may contain two or more categories of software and/or data: an operating system 415 and a time synchronization module 420. In particular, the operating system 415 may manage the data processing system's software and/or hardware resources and may coordinate execution of programs by the processor 400. The sustained oscillation detection module 420 may comprise a PMU data collection module 425, a frequency variation determination module 430, a clock time shift determination module 435, a clock adjustment communication module 440, an alert module 445, a data module 450, and a communication module 455.

The PMU data collection module 425 may be configured to receive measured information, such as, for example, time-stamped synchrophasor measurements from PMUs, e.g., the PMUs 218a, 218b, and 218c, in the distribution grid 210.

As described above, the PMUs 218a, 218b, 218c may generate synchrophasor measurements, including current and voltage phasors, frequency, and rate of change of frequency, and provide these measurements with time stamps to the data collection module 425. The frequency variation determination module 430 may be configured to determine variations in the frequency of a power signal over one or more time intervals based on these synchrophasor measurements from the PMUs 218a, 218b, 218c.

The clock time shift determination module 435 may be configured to determine a clock time shift for one or more clocks based on the variations in frequency of the respective power signals used to operate those clock(s). For example, time shifts may be determined for clocks used by the traffic management center 460 and/or the traffic signal controller 430

The clock adjustment communication module 440 may be configured to determine a clock shift adjustment for a clock that has, for example, experienced a time shift due frequency variations in the power signal used to operate the clock. In some embodiments, multiple clock shift adjustments may be determined in concert so as to synchronize multiple clocks with each other.

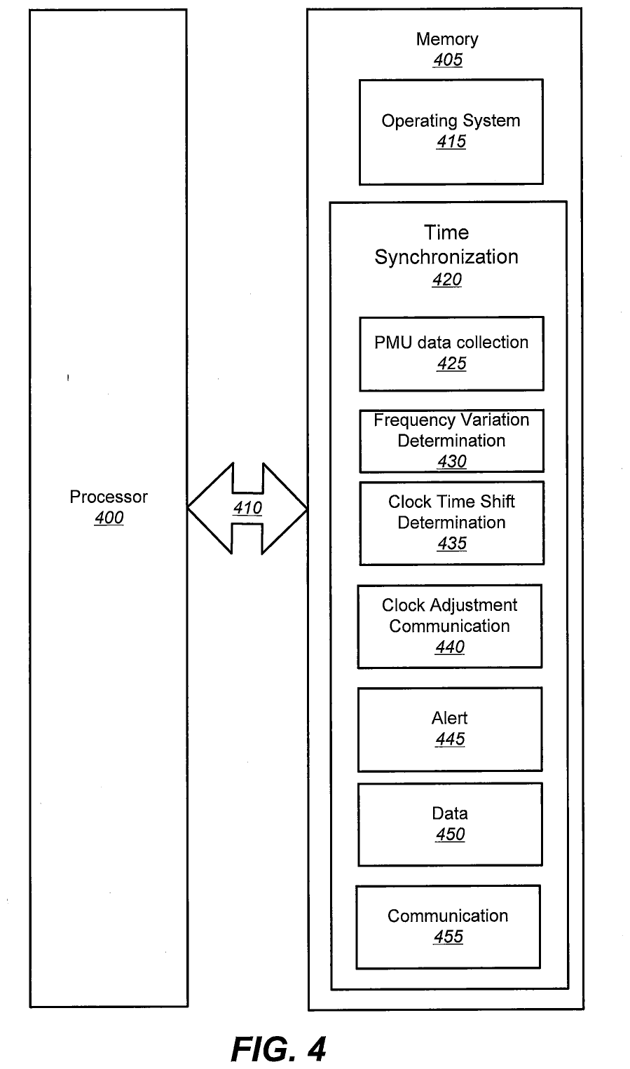

In some embodiments, Multiprotocol label switching (MPLS) technology may be used to communicate the clock time shift adjustment(s) to entities that operate based on the clock(s) associated therewith, respectively. These entities may include, for example, the traffic management center 460 and/or the traffic signal controller 430. MPLS may be used to identify packets used to communicate the clock time shift adjustments to identify the packets as containing clock shift adjustment information. MPLS provides a technique for routing packet data based on a label field rather than a destination address. An MPLS network comprises a set of nodes, which are called label switched routers (LSRs) that switch/route packets based on a label that has been added to each packet. Labels are used to define a flow of packets between two nodes or, if packets are being broadcast in a multicast operation, between a source node and multiple destination nodes. A specific path through the LSRs called a label switched path (LSP) is defined for each distinct flow, which is called a forwarding equivalence class (FEC). At intervening nodes in an LSP, an LSR may route the packet based on the MPLS label value, remove the MPLS label (pop a label), and/or impose an additional label (push a label). The label may be removed at the node from the packet at a node that is just prior to the destination node in a particular LSP. This process is sometimes referred to as “penultimate hop popping.” Referring now to FIG. 5, an example MPLS label and Internet Protocol (IP) packet are illustrated. The MPLS label is a 32-bit header that includes a 20-bit label field, a 3-bit Exp field that is reserved for experimental use, a 1-bit S field that is set to one for the oldest entry in the stack and zero for all other entries, and an 8-bit time-to-live (TTL) field that may be used to encode a hop count or time-to-live value. An MPLS label may also be referred to as an MPLS shim header. As shown in FIG. 5, multiple MPLS labels or shim headers may be included in a single IP packet. The MPLS labels or shim headers are organized as a last-in, first-out stack and are processed based on the top MPLS label or shim header. As described above, an LSR may add an MPLS label or shim header to the stack (push operation) or remove an MPLS label or shim header from the stack (pop operation).

In IP networks, such as Ethernet networks, packets are routed according to the address using a routing algorithm that typically selects the least number of “hops” to the destination. Other packet or cell networks, for example, may use similar routing algorithms for establishing connections rather than for routing each and every packet individually. Although such routing algorithms may be efficient in routing packet traffic to a destination, business considerations or governmental regulations may require that other, less efficient, traffic routing be used.

According to some embodiments of the inventive concept, an MPLS label may be used to carry an identifier that may be used to identify a communication service provider for the clock time shift adjustment packets. This may provide for a more efficient routing of the clock time shift data. Management of traffic on public roadways may also be regulated by a public governmental authority. Thus, clock time shift adjustment packets destined, for example, to the traffic management center 260 and/or the traffic signal controller 230 may incorporate an identifier using an MPLS label to indicate that the clock time shift adjustment packets are associated with a regulatory constraint of a governmental administrative authority, e.g., that the packet traffic destined for the traffic management center and/or the traffic signal controller is managed by a governmental agency. Because the clock time shift adjustment packet traffic may be associated with a government agency, it may not be subject to certain taxes, fees, and the like. The use of MPLS may allow the clock time shift adjustment traffic to be identified and processed separately including the ability to apply separate billing rates and exemptions to the traffic.

The alert module 445 may be configured to generate an alert or notification to the appropriate authority when a clock time shift has been determined that may exceed a threshold, for example, by way of the DMS 214. The alert or notification may further trigger an adjustment to one or more clocks that may be affected by the determined clock time shift.

The data module 450 may represent the power system synchrophasor measurements from the PMUs 218a, 218b, and 218c and received by the PMU data collection module 425, the threshold(s) used by the alert module 445, and other data structures used by the time synchronization module 420 for clock time shift adjustment and clock synchronization based on synchrophasor measurements obtained from one or more PMUs 218a, 218b, and 218c.

The communication module 455 may be configured to facilitate communication between the DMS 214 processor and the PMUs 218a, 218b, and 218c of FIG. 2 over the network 220, to facilitate communication of clock time shift adjustment information to entities that operate based on clocks that may be determined to have undergone a time shift due to frequency variations in a power signal, and to facilitate communication of an alert or notification to the appropriate supervisory authority over one or more wired or wireless networks upon determination that a clock may have a time shift associated therewith due to power signal frequency variations.

Although FIG. 4 illustrates hardware/software architectures that may be used in data processing systems, such as the DMS 214 processor of FIG. 2 and the data processing system 300 of FIG. 3, respectively, for clock time shift adjustment and clock synchronization based on synchrophasor measurements obtained from one or more PMUs 218a, 218b, and 218c, in accordance with some embodiments of the inventive concept it will be understood that the present invention is not limited to such a configuration but is intended to encompass any configuration capable of carrying out operations described herein.

Computer program code for carrying out operations of data processing systems discussed above with respect to FIGS. 2-4 may be written in a high-level programming language, such as Python, Java, C, and/or C++, for development convenience. In addition, computer program code for carrying out operations of the present invention may also be written in other programming languages, such as, but not limited to, interpreted languages. Some modules or routines may be written in assembly language or even micro-code to enhance performance and/or memory usage. It will be further appreciated that the functionality of any or all of the program modules may also be implemented using discrete hardware components, one or more application specific integrated circuits (ASICs), or a programmed digital signal processor or microcontroller.

Moreover, the functionality of the DMS 214 processor of FIG. 2, the data processing system 300 of FIG. 3, and the hardware/software architecture of FIG. 4, may each be implemented as a single processor system, a multi-processor system, a multi-core processor system, or even a network of stand-alone computer systems, in accordance with various embodiments of the inventive concept. Each of these processor/computer systems may be referred to as a “processor” or “data processing system.”

The data processing apparatus of FIGS. 2-4 may be used to facilitate clock time shift adjustment and clock synchronization based on synchrophasor measurements obtained from one or more PMUs 218a, 218b, and 218c, according to various embodiments described herein. These apparatus may be embodied as one or more enterprise, application, personal, pervasive and/or embedded computer systems and/or apparatus that are operable to receive, transmit, process and store data using any suitable combination of software, firmware and/or hardware and that may be standalone or interconnected by any public and/or private, real and/or virtual, wired and/or wireless network including all or a portion of the global communication network known as the Internet, and may include various types of tangible, non-transitory computer readable media. In particular, the memory 306 coupled to the processor 308 and the memory 405 coupled to the processor 400 include computer readable program code that, when executed by the respective processors, causes the respective processors to perform operations including one or more of the operations described herein with respect to FIGS. 2-7.

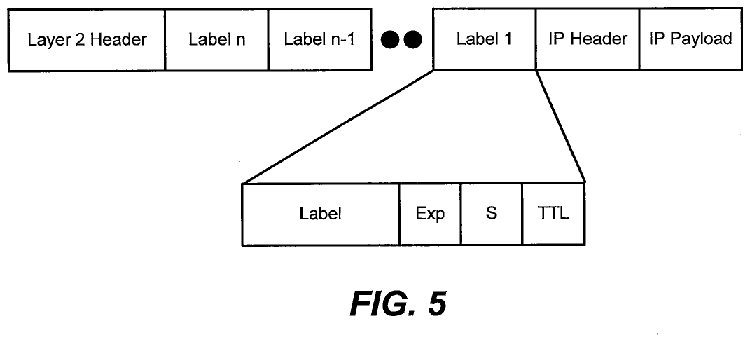

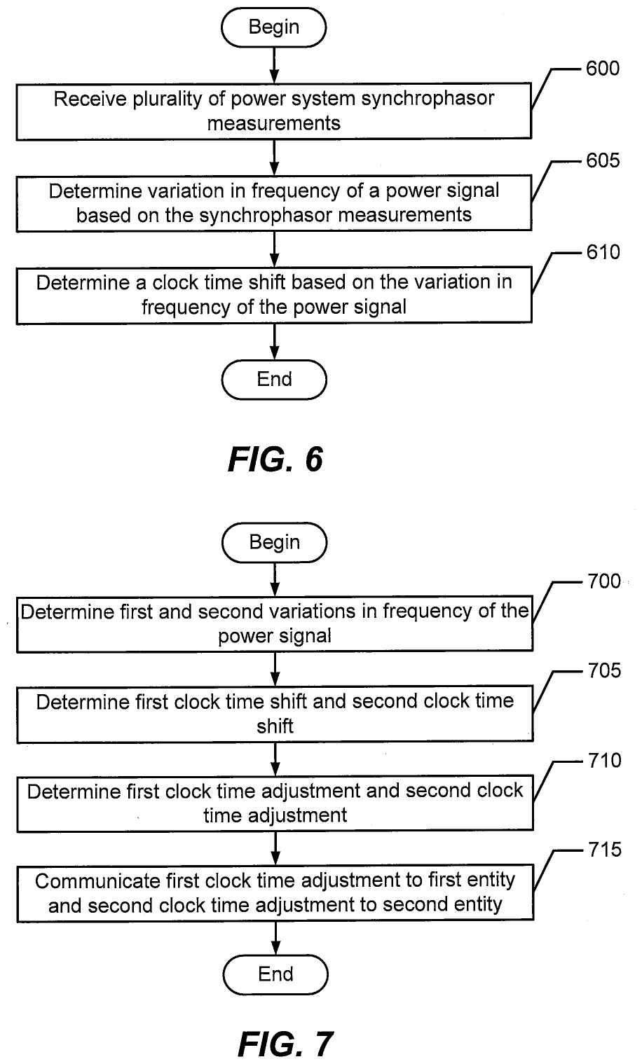

FIGS. 6-7 are flowcharts that illustrate time synchronization operations using synchrophasor measurements in a power system in accordance with some embodiments of the inventive concept. Referring to FIG. 6, operations begin at block 600 where the PMU data collection module 425 receives power system synchrophasor measurements obtained from one or more PMUs 218a, 218b, and 218c in accordance with some embodiments of the inventive concept. The frequency variation determination module 430 determines a variation in frequency of the power signal based on the synchrophasor measurements at block 605. The clock time shift determination module 435 determines a clock time shift based on the variation in frequency of the power signal at block 610. In accordance with various embodiments of the inventive concept, the clock adjustment communication module 440 may determine a clock time adjustment based on the clock time shift, which may be communicated to an entity that operates based on the clock. Incorporation of the clock time adjustment may improve the clock's accuracy and/or may synchronize the clock with another clock or with a reference. The alert module 445 may also communicate an alert to an authority associated with the clock notifying the authority that the clock's time may be off due to deviations in the frequency of the power signal that powers the clock. The alert may be sent, for example, when the clock time adjustment exceeds a threshold and may allow the authority to decide whether to update the clock with a clock time adjustment or, if the clock time adjustment is relatively small, wait until the clock has deviated by a greater amount before applying a clock time adjustment to the clock.

Referring now to FIG. 7, operations of synchronizing two clocks associated with different entities, such as the traffic management center 260 and the signal controller 230, according to some embodiments of the inventive concept, will be described. Operations begin at block 700 where the frequency variation determination module 430 determines first and second variations in frequency of the power signal(s) used to drive clocks associated with two different entities, such as the traffic management center 260 and the signal controller 230, based on power system synchrophasor measurements. The clock time shift determination module 435 determines clock time shifts for each of the clocks are determined at block 705 and the clock adjustment communication module 440 determines clock time adjustments for each of the clocks at block 710. The clock adjustment communication module 440 may communicate the first clock time adjustment to the traffic management center 260 (first entity) and the second clock time adjustment to the traffic signal controller 230 (second entity) at block 715. In some embodiments, the traffic management center 260 and the traffic signal controller 230 may apply these clock time adjustments to their respective clocks so as to improve synchronization between their clocks. The improved synchronization may allow the traffic management center 260 to better control the operation of traffic control units, such as the traffic lights 240, through the traffic signal controller 230 because the traffic management center 260 and the traffic signal controller 230 may have less difference in their time reference standards.

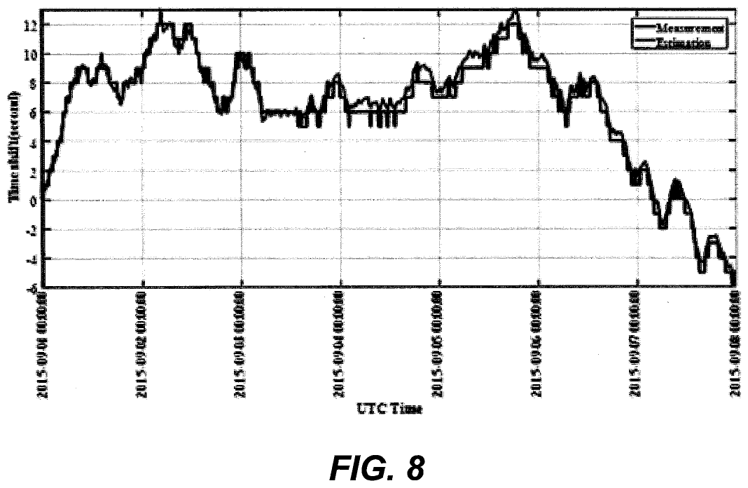

FIG. 8 is a chart that illustrates predicted and measured time shift based on power system frequency variations in accordance with some embodiments of the inventive concept. As shown in FIG. 8, over a period of approximately seven days, a clock may run fast and run slow at various times so as to be over 12 seconds ahead at some points in time and to be approximately 6 seconds behind at another point in time due to variations in the frequency of a power signal. FIG. 8 also shows that the clock time shift determination module 435 may determine the time shift in the clock with a generally high degree of accuracy based on synchrophasor measurements in accordance with the embodiments described herein as there is relatively little difference between the measured time shift and the estimated time shift according to some embodiments of the inventive concept described herein.

Embodiments of the inventive concept will now be described by way of examples in which a clock time shift due to frequency variation is estimated based on synchrophasor measurements and compared with actual timestamp measurements to determine that actual time shift.

Based on the description of the electric clock schemas above, the time of an electric clock can be expressed as follows:

t=T₀*f/f₀

where T₀ is the interval of the measurement samples. The PMUs may collect phasor measurements at a rate of ten points per second. In this case, T₀ is 0.1 seconds. The measurement frequency is f and f₀ is the nominal frequency value. Therefore, t is the clock time corresponding to the given time interval T₀. Assuming the frequency between each measurement sample is stable, the duration of each one hundred milliseconds is recognized as (f/60)*0.1 seconds for electric clocks. Because the frequency is not constant, the time drift may accumulate as time goes by. A start time may be set up as a zero drift reference and an end time as an analyzed object, and an estimation may be generated of the time difference between GPS time and the electric clock during a given time period based on the synchrophasor measurements.

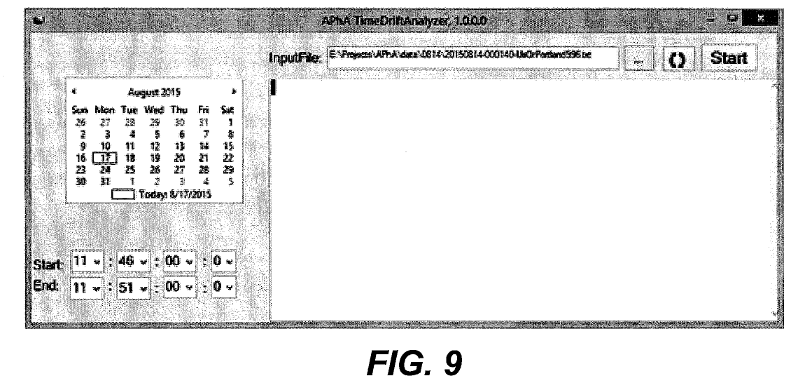

Using PMU synchrophasor measurements, a time drift analyzer tool, which may encompass the time synchronization module 420 of FIG. 4, may be configured to estimate the time drift from a given time reference at which point the time has zero drift. In some embodiments, the time drift analyzer may be programmed in the C# programming language in Visual Studio. An example Graphical User Interface (GUI) is shown in FIG. 9.

In the form of FIG. 9, clients can select the date through the calendar, pick the start time and end time on the left part of the form, then load a synchrophasor data file by clicking the load button . . . . By clicking the “Start” button, the data may be loaded an analyzed. The time drift estimation result of the duration selected by the user may be displayed in the window below the input file dialog.

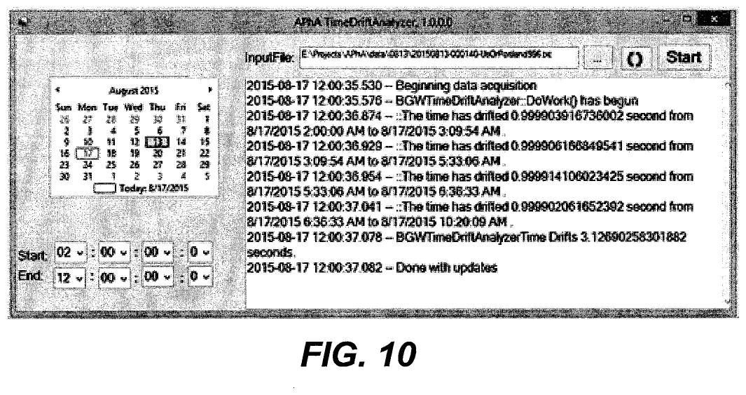

FIG. 10 shows an example of time drift estimation. It estimates the time drift from 02:00:00.0 August 13 to 12:00:00.0 August 13. By analyzing the synchrophasor measurements, the result in the window shows the start time and end time when the drift is up to plus or minus 1 second, and the total drift at the end. In this example, the clock has drifted about 3.127 seconds during the 10 hours.

By analyzing the electricity frequency measured by PMUs, the estimation of time drift can be obtained by the tool. The drift calculated by the tool may be verified to ensure that it is consistent with the true time drift in traffic signal controllers. If the time drift estimation is proved to be close to the real drift, it is believed that the power frequency can be used to estimate time drift in electric clocks, including, but not limited to traffic signals.

According to the National Transportation Communications for Intelligent Transportation System Protocol (NTCIP), the internal information of the traffic signal controller, which is in compliance with the protocol, is able to be queried by successful connection and queries. By creating a correct Management Information Base (MIB) with a specific object ID for targeting information, the device recognizes the query and replies with corresponding information.

Referring again to FIG. 2, the signal controller 230 is connected to the DMS 214, e.g., host computer, over the network 220. The DMS 214 may send a request to the signal controller 230 querying the internal clock time. The signal controller 230 receives the query and returns the current time of the internal clock. Assuming the communication speed in both directions is identical, the DMS 214 may estimate the local time, which comprise with the Network Time Protocol (NTP), as the moment the device replies with an answer counting the double-directional communication time. Both the signal controller 230 internal time and the local host time at the same moment are obtained and recorded at the DMS 214. In some embodiments, the request is sent every second to monitor the time drift continuously.

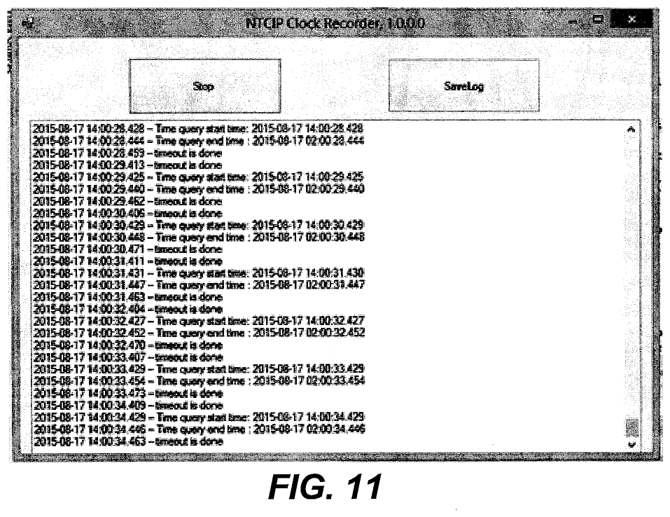

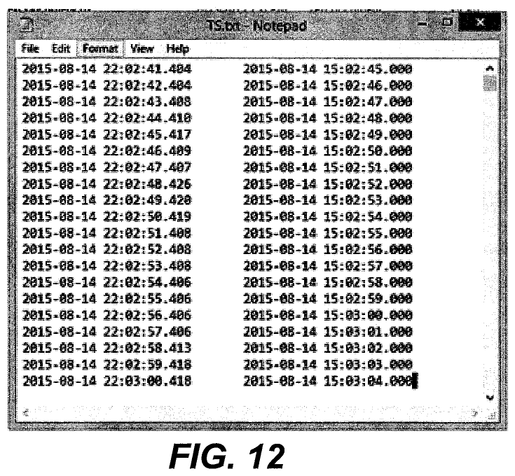

The interface to initialize the query and display the query log is shown in FIG. 11. By clicking the “Start” button, the communication is established and the host starts to send queries continuously to the controller. The communication log is displayed in the window. The query result may be exported in a text file as shown in FIG. 12. There are two columns in the file. The left column represents the time stamps of the internet clock UTC time. The right column shows the timestamps of the internal clock installed in the signal controller 230. It is set up to be local time (PST). Each row stands for the timestamps from different clocks, i.e., signal controller clock and, e.g., GPS UTC time at the same moment. From the query result, it can be seen that the signal controller 230 does not have milliseconds, which is consistent with the fundamental principle that electric clocks count in seconds as explained above.

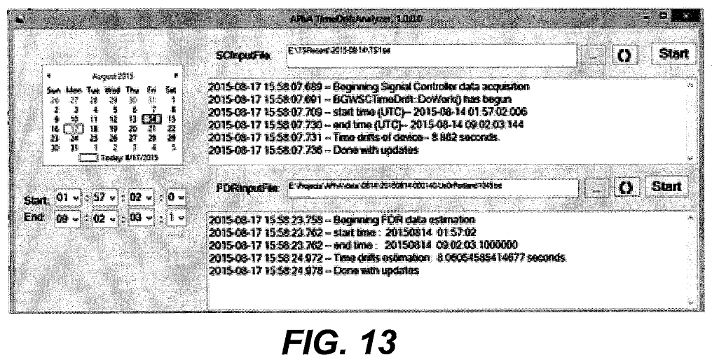

Because the timestamps of the signal controller 230 clock are considered as the real applied electric clock in the field, the query result can be used to verify the accuracy of time drift or time shift estimation based on synchrophasor measurements according to some embodiments of the inventive concept. The implementation of the comparison may show the drifts for identical duration simultaneously. An example of the comparison result is shown in FIG. 13.

A user may select the start time and end time (UTC time) for comparison. The start time may default as the reference with zero drift. The query result of signal controller 230 time stamp record file may be loaded by clicking the upper load button and the actual time drift may be computed by clicking the corresponding start button. For the same time duration, the user may load synchrophasor data by clicking the lower load button and compute the time shift or time drift estimation by clicking the corresponding start button. As shown in FIG. 13, when the time duration is set to be from 01:57:02.000 August 14 to 09:02:03.100 August 14, the actual time drift is shown in the right upper window as 8.862 seconds, and the estimation is displayed in the right lower window as 8.061 seconds. The estimation is close to the actual drift read from the signal controller 230 with an error less than one second.

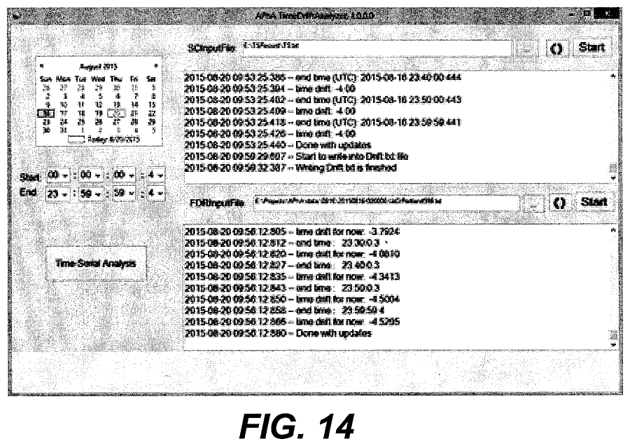

To validate the accuracy of estimating time shift or time drift in an electric clock based on frequency information from synchrophasor measurements, the estimation may be performed over a long time duration and compared to the measurement of actual time drift. The comparison of estimation and measurement of time drift can be done in time-serial to show the error in a certain interval. The same approach as that described above may be used to compute the estimation of electric clock time drift caused by power frequency fluctuation and comparing the estimation with the actual drift obtained from a signal controller 230. In this application, the start time is set to be the unique zero time drift reference; the end time is set to be the final time to be observed. The time drift may be computed every 10 minutes until the final end time. It may, therefore, be possible to see how the time drift changes over time. FIG. 14 illustrates a comparison between estimated and actual time drift over a long-term time duration. As compared with the GUI of FIG. 13, there is one more button in the lower left area. This button is used to combine the time drift results from both estimation and actual measurement records and write the comparison result into a local text file.

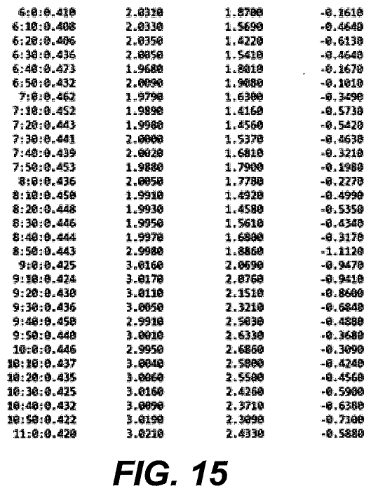

As shown in the example in FIG. 14, the time duration is selected from midnight of August 16 to the last second of the day. By loading the recorded time stamps of the internal clock in the signal controller 230, and then clicking the start button on the top, the real-time drifts of every 10 minutes from the start time may be computed and the result may be shown in the upper window. By loading the measurements of certain PMUs, and then clicking the start button in the middle, thee estimation of time drifts of every 10 minutes from the start time may be computed and the results may be shown in the lower window. At the end, the user can click the “Time-Serial Analysis” button to combine the results of both time shift estimation and actual measurement and write these results in a local text file. Upon completion of the writing process, one or more messages may be displayed in the upper dialog indicating that the process is done. FIG. 15 illustrates the content of the local text file for the present example.

There are four columns in the file representing the time stamp, the real-time drift of the internal clock in the signal controller, the corresponding time drift estimation computing based on PMU power frequency measurement, and the difference between the real drift and the estimation respectively. For each row, the time stamp is set as the present end time. The time drift results in the second and third columns are the corresponding drifts from the unique start time (00:00:00.4 am, August 16 in the example shown in FIG. 14) to the present end time as indicated in the first column. The result in the last column equals the measured drift subtracted from estimated drift. It can be seen from the last column of this short time analysis that the errors are mostly within 1 second. However, such a short time performance may not sufficient to verify the accuracy of the estimations. A series of tests have been conducted to verify the time drift estimation accuracy based on synchrophasor information from different PMUs and long durations.

The time drift estimation based on power grid frequency measurement is demonstrated to be capable of estimating the real-time drift of a local traffic signal controller clock. There are multiple PMUs available in a specific power grid. Using different input data, e.g., synchrophasor frequency information, produces different estimation results. Therefore, the drift estimation results are compared with measured drift results using different frequency measurements in the Western Electricity Coordinating Council (WECC) for the same day (August 19 as an example).

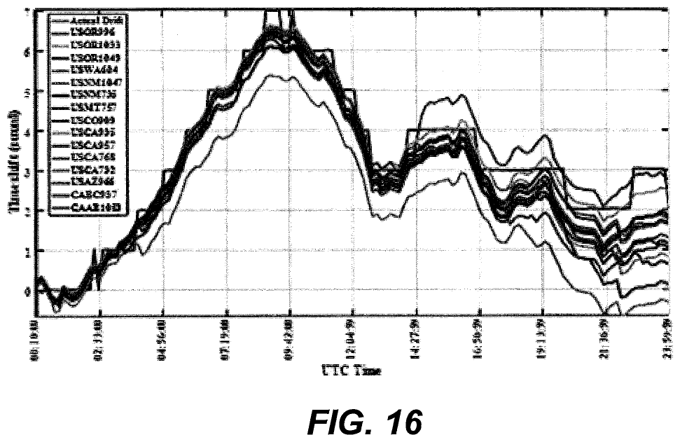

FIG. 16 shows the estimations of time drifts based on measurements from different PMUs in WECC on August 19. Some of them deviate from the actual drift significantly. Conversely, estimations based on different PMU data diverge obviously at the end of the day.

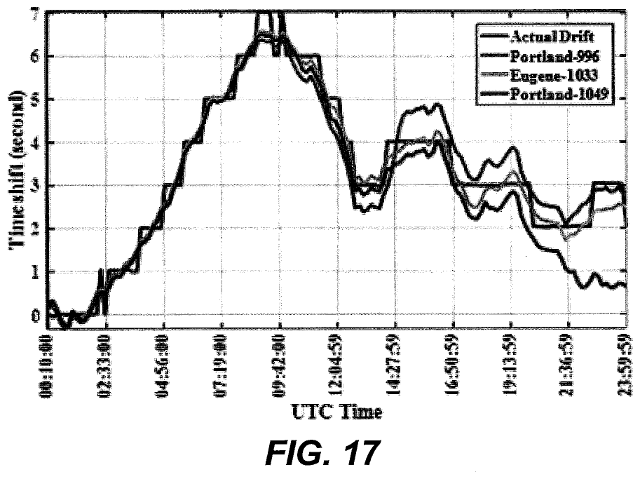

The same result appears on the comparison of the PMUs located in Oregon, which is the location where the experiment was conducted, as shown in FIG. 17. There are two PMUs installed in Portland and one in Eugene. In FIG. 17, the divergence of time drift estimation based on these three PMUs during the late hours of the day can be seen. Moreover, the estimation result from the PMUs installed in Portland is inferior to that of the PMU in Eugene, even though the source of electric clock drift measurement is from a building located in Portland. Therefore, the estimation of time drift from an individual frequency signal may not track time shift as reliably as when data from multiple PMUs is used. The same tests on other days, August 20 and August 21, provide similar estimation results.

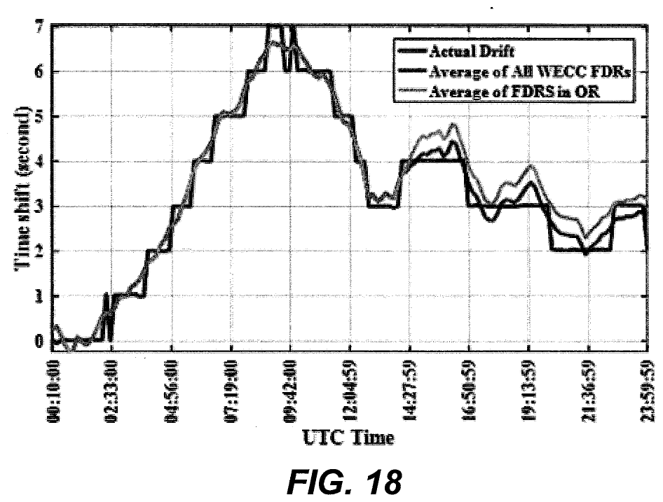

By combining measurements from multiple PMUs, an average frequency over the WECC power grid may be determined. The estimation of time drift based on the average frequency over multiple PMUs may be compared with measured drift results. Thus, the frequency averaging may be applied to the frequency measurements described above with respect to FIG. 17. FIG. 18 illustrates a comparison actual time drift, the estimated time drift based on average frequency for all PMUs in WECC, and the estimated time drift based on all PMUs in Oregon for the same day.

As can be seen in FIG. 18, the estimation results based on synchrophasor frequency information from multiple PMUs are closer to the measured drift results than the estimate based on an individual frequency. The stepwise curve is the actual measured time drift while the other curves are estimates based on different frequency data from different PMUs. I can be seen that the result of the average frequency of all PMUs installed in WECC is more consistent with the actual drift than the result of the average frequency of PMUs installed in Oregon. This demonstration is a 24-hour continuous estimation. For those daily-self synchronized signal controllers 230, which may be set to be self-time-corrected regularly at midnight or sometime during a day, the above-described performance may prove the accuracy of daily electric clock time drift estimations that have an error of less than one second.

Embodiments of the inventive concept may also be used to estimate long-term time drift of an electric clock. Many old traffic signal controllers in old cities are not reset regularly. Because time drift is a cumulative variable, it may be desirable for the estimation to provide useful accuracy over long time periods where the time drift may accumulate.

For a long duration analysis, there are a few differences from the previous analysis for a single day. First, multiple data files may be imported because the synchrophasor frequency data for a same day may be in an individual text file. Second, the selection date and time of the zero-drift reference and end time may be selected based on user or customer input.

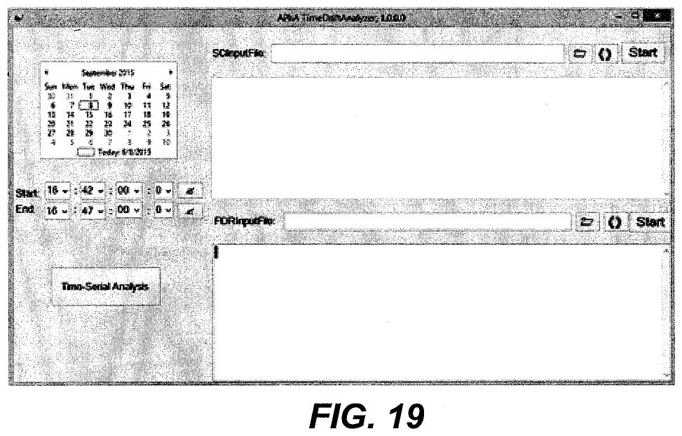

The analysis platform for a long-term duration analysis may be implemented in C#. The GUI for the long-term duration analysis, according to some embodiments of the inventive concept, is shown in FIG. 19.

As shown in FIG. 19, the interface is similar to the interface of FIG. 9 as the functionality is similar. The primary difference is the increase in data processing and computations. For example, PMU frequency data may include 864,000 records including frequency and timestamp information, a weekly analysis may include 6,048,000 records, and a monthly computation may involve over 25 million records. Thus, certain modules may be designed to work efficiently on large amounts of data. The interface of FIG. 19 is similar to that of FIG. 9, but includes check buttons next to the start time and end time selection dialogs. Because the analyzed data time duration is expected to span multiple days, users can choose the data and time of the zero-drift reference time through the calendar time selection dialog, and then click the check button beside the start time. The next step is to choose the end time and confirm it by clicking the check button following the end time. The interface can allow an analysis of the time drift from a given start time and terminal time within the same month with a 10 minute interval granularity.

Referring again to FIG. 8, the based on the available data record, the time drift from 12:00:00 AM September 1 to 23:59:59 PM September 7 (UTC time) is estimated, and the result is compared with the measured time drift result. In FIG. 8, the black stepwise curve is the actual time drift from the controller. The red curve is the estimation of time drift based on frequency measurement from FNET/GridEye. As can be seen in FIG. 8, for a long-term duration analysis, the estimation of the time drift closely follows the actual measured time drift over multiple days. Moreover, the error doesn't increase as time goes on and the estimation error is within 1 second throughout the test period.

Embodiments of the inventive concept may provide a synchrophasor measurement-based method for determining a clock time shift due to frequency variation in the power signal used to power the clock. The clock time shift determination may be used, for example, to correct the clock when it gets too far off from the actual time and/or to synchronize multiple clocks that cooperate with each other to provide some capability or functionality, such as a traffic management center and a traffic signal controller, which cooperate to operate traffic lights and other traffic control units to facilitate the flow of vehicles along roads. Such synchronization may become increasingly important as self-driving vehicles are introduced to the roadways as the clocks in the vehicles and clocks in the traffic control infrastructure may need to be synchronized to receive the full benefits of autonomous driving.

### FURTHER DEFINITIONS AND EMBODIMENTS

In the above-description of various embodiments of the present disclosure, aspects of the present disclosure may be illustrated and described herein in any of a number of patentable classes or contexts including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product comprising one or more computer readable media having computer readable program code embodied thereon.

Any combination of one or more computer readable media may be used. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can,communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, LabVIEW, dynamic programming languages, such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The present disclosure of embodiments has been presented for purposes of illustration and description, but is not intended to be exhaustive or limited to the disclosure in the form disclosed. Many variations and modifications can be made to the embodiments without substantially departing from the principles of the present invention. All such variations and modifications are intended to be included herein within the scope of the present invention.

What is claimed is:

1. A method comprising:
performing by a processor:
receiving a plurality of power system synchrophasor measurements over a time interval from a plurality of phasor measurement units (PMUs) in a power system;
determining a variation in frequency of a power signal generated by the power system based on the plurality of power system synchrophasor measurements; and
determining a clock time shift based on the variation in frequency of the power signal.

2. The method of claim 1, wherein determining the variation in frequency of the power signal comprises:
determining a first variation in frequency of the power signal based on at least a first portion of the plurality of power system synchrophasor measurements; and
determining a second variation in frequency of the power signal based on at least a second portion of the plurality of power system synchrophasor measurements;
wherein determining the clock time shift comprises:
determining a first clock time shift based on the first variation in frequency of the power signal; and
determining a second clock time shift based on the second variation in frequency of the power signal.

3. The method of claim 2, further comprising:
determining a first clock time adjustment and a second clock time adjustment based on the first clock time shift and the second clock time shift, respectively, to reduce a time offset between the first clock and the second clock.

4. The method of claim 3, wherein a vehicular traffic management center operates based on the first clock; and
wherein a traffic signal controller operates based on the second clock, the traffic signal controller being under control of the vehicular traffic management center.

5. The method of claim 4, further comprising:
communicating the first clock time adjustment to the vehicular traffic management center; and
communicating the second clock time adjustment to the traffic signal controller.

6. The method of claim 5, wherein communicating the first clock time adjustment comprises communicating the first clock time adjustment to the vehicular traffic management center via a packet switched connection; and
wherein communicating the second clock time adjustment comprises communicating the second clock time adjustment to the traffic signal controller via the packet switched connection.

7. The method of claim 6, wherein the packet switched connection comprises an Ethernet connection.

8. The method of claim 7, wherein the first clock time adjustment comprises first Multiprotocol Label Switching (MPLS) packet data; and
wherein the second clock time adjustment comprises second MPLS packet data.

9. The system of claim 8, wherein a first label of the first MPLS packet data comprises a first identifier that identifies a first communication service provider; and
wherein a second label of the second MPLS packet data comprises a second identifier that identifies a second communication service provider.

10. The method of claim 1, further comprising:
determining a clock time adjustment based on the clock time shift; and
communicating the clock time adjustment to an entity that operates based on the clock.

11. The method of claim 1, further comprising:
generating an alert based on the clock time shift.

12. The method of claim 11, further comprising:
communicating the alert to an entity that operates based on the clock.

13. A system, comprising:
a processor; and
a memory coupled to the processor and comprising computer readable program code embodied in the memory that is executable by the processor to perform operations comprising:
receiving a plurality of power system synchrophasor measurements over a time interval from a plurality of phasor measurement units (PMUs) in a power system;
determining a variation in frequency of a power signal generated by the power system based on the plurality of power system synchrophasor measurements; and
determining a clock time shift based on the variation in frequency of the power signal.

14. The system of claim 13, wherein determining the variation in frequency of the power signal comprises:
determining a first variation in frequency of the power signal based on at least a first portion of the plurality of power system synchrophasor measurements; and
determining a second variation in frequency of the power signal based on at least a second portion of the plurality of power system synchrophasor measurements;
wherein determining the clock time shift comprises:
determining a first clock time shift based on the first variation in frequency of the power signal; and
determining a second clock time shift based on the second variation in frequency of the power signal.

15. The system of claim 14, wherein the operations further comprise:
determining a first clock time adjustment and a second clock time adjustment based on the first clock time shift and the second clock time shift, respectively, to reduce a time offset between the first clock and the second clock.

16. The system of claim 15, wherein a vehicular traffic management center operates based on the first clock; and
wherein a traffic signal controller operates based on the second clock, the traffic signal controller being under control of the vehicular traffic management center.

17. The system of claim 16, wherein the operations further comprise: communicating the first clock time adjustment to the vehicular traffic management center; and
communicating the second clock time adjustment to the traffic signal controller.

18. A computer program product, comprising:
a tangible computer readable storage medium comprising computer readable program code embodied in the medium that is executable by a processor to perform operations comprising:
determining a first variation in frequency of the power signal based on at least a first portion of the plurality of power system synchrophasor measurements; and
determining a second variation in frequency of the power signal based on at least a second portion of the plurality of power system synchrophasor measurements;
wherein determining the clock time shift comprises:
determining a first clock time shift based on the first variation in frequency of the power signal; and
determining a second clock time shift based on the second variation in frequency of the power signal.

19. The computer program product of claim 18, wherein the operations further comprise:
determining a first clock time adjustment and a second clock time adjustment based on the first clock time shift and the second clock time shift, respectively, to reduce a time offset between the first clock and the second clock.

20. The computer program product of claim 19, wherein a vehicular traffic management center operates based on the first clock; and
wherein a traffic signal controller operates based on the second clock, the traffic signal controller being under control of the vehicular traffic management center;
wherein the operations further comprise:
communicating the first clock time adjustment to the vehicular traffic management center; and
communicating the second clock time adjustment to the traffic signal controller.
